(19) United States
(12) Patent Application Publication
(10) Pub. No.: US 2026/0219345 A1
(43) Pub. Date: Jul. 30, 2026

(54) CO-REGISTERED PARAMETRIC MAPPING USING ECHO-PLANAR IMAGING (EPI) CARDIOVASCULAR MAGNETIC RESONANCE (CMR)

(71) Applicants: Siemens Healthineers AG, Forchheim (DE); The Cleveland Clinic Foundation, Cleveland, OH (US)

(72) Inventors: Xiaoming Bi, Oak Park, CA (US); Christopher T. Nguyen, Beachwood, OH (US); Yuchi Liu, Ann Arbor, MI (US); Danielle Kara, University Heights, OH (US); Dingheng Mai, Cleveland Heights, OH (US)

(21) Appl. No.: 19/036,109

(22) Filed: Jan. 24, 2025

(51) Int. Cl. G01R 33/561; G01R 33/563

(52) U.S. Cl. CPC G01R 33/5616; G01R 33/56375

(57) ABSTRACT

A medical imaging system comprises: a memory storing computer-executable instructions; and at least one processor configured to execute the computer-executable instructions to cause the medical imaging system to: acquire a plurality of series of slice images of at least a portion of a heart of a patient using spin-echo echo planar imaging readouts and a plurality of different magnetic resonance imaging sequences, and generate a plurality of co-registered parametric mappings based on the plurality of series of slice images, each of the plurality of co-registered parametric mappings corresponding to a magnetic resonance imaging sequence among the plurality of different magnetic resonance imaging sequences.

### TECHNICAL FIELD

Example embodiments relate to methods, apparatuses and/or non-transitory computer-readable mediums for co-registered parametric mapping using Echo-Planar Imaging (EPI) Cardiovascular Magnetic Resonance (CMR).

### BACKGROUND

Quantitative characterization of myocardial tissue through relaxation and diffusion metrics provides a non-invasive way to assess myocardial tissue composition. In contrast to qualitative imaging, quantitative Magnetic Resonance Imaging (MRI) provides a more precise, reproducible, and objective assessment of both focal and diffuse diseases. Various quantitative parameters serve as useful biomarkers for distinct diseases. For instance, mapping T1 and T2 relaxation parameters (T1 and T2 maps) can detect fibrosis, edema, and/or infectious diseases, while mapping the diffusion parameter (e.g., the apparent diffusion coefficient (ADC) via an ADC map) helps quantify microstructural changes and identify early tissue injury markers. The distinct contrast provided by these parameters makes multi-parametric Cardiovascular Magnetic Resonance (CMR) imaging useful for comprehensive disease characterization.

### SUMMARY

At least one example embodiment provides a medical imaging system comprising: at least one processor and a memory storing computer-executable instructions. The at least one processor is configured to execute the computer-executable instructions to cause the medical imaging system to: acquire a plurality of series of slice images of at least a portion of a heart of a patient using spin-echo echo planar imaging readouts and a plurality of different magnetic resonance imaging sequences; and generate a plurality of co-registered parametric mappings based on the plurality of series of slice images, each of the plurality of co-registered parametric mappings corresponding to a magnetic resonance imaging sequence among the plurality of different magnetic resonance imaging sequences.

At least one example embodiment provides a medical imaging system comprising: means for acquiring a plurality of series of slice images of at least a portion of a heart of a patient using spin-echo echo planar imaging readouts and a plurality of different magnetic resonance imaging sequences; and means for generating a plurality of co-registered parametric mappings based on the plurality of series of slice images, each of the plurality of co-registered parametric mappings corresponding to a magnetic resonance imaging sequence among the plurality of different magnetic resonance imaging sequences.

According to one or more example embodiments, the plurality of co-registered parametric mappings may provide quantitative characterization of the portion of the heart.

The at least one processor may be configured to execute the computer-executable instructions to cause the medical imaging system to display the plurality of co-registered parametric mappings.

The at least one processor may be configured to execute the computer-executable instructions to cause the medical imaging system to display the plurality of co-registered parametric mappings overlayed on one or more of the slice images.

The plurality of different magnetic resonance imaging sequences may include T1, T2 and diffusion encoding.

The plurality of series of slice images may be acquired under free breathing conditions.

The plurality of series of slice images may include a plurality of series of T1 weighted slice images, a plurality of series of T2 weighted slice images and a plurality of series of diffusion weighted slice images.

The at least one processor may be configured to execute the computer-executable instructions to cause the medical imaging system to acquire the plurality of series of T1 weighted slice images, the plurality of series of T2 weighted slice images and the plurality of series of diffusion weighted slice images during the same cardiac phase.

The at least one processor may be configured to execute the computer-executable instructions to cause the medical imaging system to acquire the plurality of series of T1 weighted slice images using at least two different inversion times.

The at least one processor may be configured to execute the computer-executable instructions to cause the medical imaging system to apply a nonselective adiabatic inversion pulse, and to acquire at least a first of the plurality of series of T1 weighted slice images with interleaved slice acquisition, wherein acquisition of respective T1 weighted slice images in the first of the plurality of series of T1 weighted slice images is separated by a duration of a heartbeat.

The at least one processor may be configured to execute the computer-executable instructions to cause the medical imaging system to acquire the plurality of series of T2 weighted slice images by varying an echo time used to acquire each of the plurality of series of T2 weighted slice images.

The at least one processor may be configured to execute the computer-executable instructions to cause the medical imaging system to acquire the plurality of series of diffusion weighted slice images by applying second-order motion compensated diffusion gradients with different b values and directions.

The medical imaging system may further include a magnetic resonance imaging device configured to acquire the plurality of series of slice images.

At least one other example embodiment provides a non-transitory computer-readable storage medium storing computer-executable instructions that, when executed by at least one processor at an medical imaging system, cause the medical imaging system to perform a method for generating a plurality of co-registered parametric mappings of at least a portion of a heart of a patient, the method comprising: acquiring a plurality of series of slice images of at least the portion of the heart using spin-echo echo planar imaging readouts and a plurality of different magnetic resonance imaging sequences; and generating the plurality of co-registered parametric mappings based on the plurality of series of slice images, each of the plurality of co-registered parametric mappings corresponding to a magnetic resonance imaging sequence among the plurality of different magnetic resonance imaging sequences.

At least one other example embodiment provides a method for generating a plurality of co-registered parametric mappings of at least a portion of a heart of a patient, the method comprising: acquiring a plurality of series of slice images of at least the portion of the heart using spin-echo echo planar imaging readouts and a plurality of different magnetic resonance imaging sequences; and generating the plurality of co-registered parametric mappings based on the plurality of series of slice images, each of the plurality of co-registered parametric mappings corresponding to a magnetic resonance imaging sequence among the plurality of different magnetic resonance imaging sequences.

At least one other example embodiment provides a computer program or computer program product including program segments and/or computer-executable instructions that, when executed by at least one processor at an medical imaging system, cause the medical imaging system to perform a method for generating a plurality of co-registered parametric mappings of at least a portion of a heart of a patient, the method comprising: acquiring a plurality of series of slice images of at least the portion of the heart using spin-echo echo planar imaging readouts and a plurality of different magnetic resonance imaging sequences; and generating the plurality of co-registered parametric mappings based on the plurality of series of slice images, each of the plurality of co-registered parametric mappings corresponding to a magnetic resonance imaging sequence among the plurality of different magnetic resonance imaging sequences.

The plurality of co-registered parametric mappings may provide quantitative characterization of the portion of the heart.

The method may further include displaying the plurality of co-registered parametric mappings overlayed on one or more of the slice images.

The plurality of series of slice images may include a plurality of series of T1 weighted slice images, a plurality of series of T2 weighted slice images and a plurality of series of diffusion weighted slice images.

The acquiring may include acquiring the plurality of series of T1 weighted slice images, the plurality of series of T2 weighted slice images and the plurality of series of diffusion weighted slice images during the same cardiac phase.

The acquiring may include: acquiring at least a first of the plurality of series of T1 weighted slice images with interleaved slice acquisition after applying a nonselective adiabatic inversion pulse, wherein acquisition of respective T1 weighted slice images in the first of the plurality of series of T1 weighted slice images is separated by a duration of a heartbeat, acquiring the plurality of series of T2 weighted slice images by varying an echo time used to acquire each of the plurality of series of T2 weighted slice images, and acquiring the plurality of series of diffusion weighted slice images by applying second-order motion compensated diffusion gradients with different b values and directions.

### BRIEF DESCRIPTION OF THE DRAWINGS

Example embodiments of the present invention will become apparent from the following detailed description considered in conjunction with the accompanying drawings. The drawings, however, are only examples and schematic solely for the purpose of illustration and do not limit the present invention.

FIG. 1 is a block diagram of a medical imaging system for implementing one or more example embodiments.

FIG. 2 is a flow chart illustrating a method according to example embodiments.

FIG. 3 is a flow chart illustrating a method for acquiring multiple series of slice images, according to example embodiments.

FIG. 4A illustrates a sequence scheme for obtaining multiple series of T1 weighted slice images, according example embodiments.

FIG. 4B is a pulse sequence for acquiring T1 weighted slice images, according to example embodiments.

FIG. 5A illustrates a sequence scheme for obtaining multiple series of T2 weighted slice images, according example embodiments.

FIG. 5B is a pulse sequence for acquiring T2 weighted slice images, according to example embodiments.

FIG. 6A illustrates a sequence scheme for obtaining multiple series of diffusion weighted slice images, according example embodiments.

FIG. 6B is a pulse sequence for acquiring diffusion weighted slice images, according to example embodiments.

FIG. 7 is a flow chart illustrating a method for image reconstruction, according to example embodiments.

FIG. 8 is a flow chart illustrating a method for motion correction, according to example embodiments.

FIG. 9A is an example visual representation of the example embodiment shown in FIG. 8.

FIG. 9B illustrates an example T1, T2 and ADC map, according to example embodiments.

FIG. 10 illustrates example images with different contrast weightings, representative curve fits from parametric mappings, and example weighted maps.

FIGS. 11A, 11B and 11C illustrate example T1, T2, and ADC quantification results in phantoms.

FIG. 12 illustrates example representative maps in a healthy volunteer.

FIG. 13 illustrates examples of averaged T1 and T2 values over a set of healthy volunteers.

FIG. 14 illustrates example co-registered parametric maps and clinical sequences on an older male with clinically suspected cardiac amyloidosis.

FIG. 15 illustrates example co-registered parametric maps and clinical sequences on an myocardial infarction swine.

FIG. 16 illustrates example effectiveness of motion correction in connection with example embodiments.

### DETAILED DESCRIPTION

Various example embodiments will now be described more fully with reference to the accompanying drawings in which only some example embodiments are shown. Specific structural and functional details disclosed herein are merely representative for purposes of describing example embodiments. Example embodiments, however, may be embodied in various different forms, and should not be construed as being limited to only the illustrated embodiments. Rather, the illustrated embodiments are provided as examples so that this disclosure will be thorough and complete, and will fully convey the concepts of this disclosure to those skilled in the art. Accordingly, known processes, elements, and techniques, may not be described with respect to some example embodiments. Unless otherwise noted, like reference characters denote like elements throughout the attached drawings and written description, and thus descriptions will not be repeated. The present invention, however, may be embodied in many alternate forms and should not be construed as limited to only the example embodiments set forth herein.

Detailed illustrative embodiments are disclosed herein. However, specific structural and functional details disclosed herein are merely representative for purposes of describing example embodiments. The example embodiments may, however, be embodied in many alternate forms and should not be construed as limited to only the embodiments set forth herein.

Independent of the grammatical term usage, individuals with male, female or other gender identities are included within the term.

Clinically, a T1 map is typically acquired using Modified Look-Locker Inversion recovery (MOLLI) or Saturation Recovery Single-Shot Acquisition (SASHA) techniques. A T2 map is typically acquired using T2-prepared Balanced Steady-State Free Precession (SSFP) or Fast Low Angle SHot (FLASH) gradient echo sequences. However, these methods require breath-holding to reduce and/or minimize respiratory motion effects, which is potentially challenging for patients. Furthermore, mapping different parameters (e.g., T1 relaxation time, T2 relaxation time, etc.) requires separate acquisitions, potentially leading to misaligned maps and inconsistent breath-holding quality.

Methods for simultaneous acquisition of T1 and T2 weighted images, both with and without breath-holding, aim to enable co-registered multiparametric clinical evaluations, enhance patient comfort, and reduce Magnetic Resonance (MR) measurement times. However, Cardiac Magnetic Resonance Fingerprinting (MRF), employing dictionary matching and incoherent undersampled encoding patterns, and MR Multitasking, utilizing low-rank tensor models for cardiac respiratory motion, along with other simultaneous multiparametric mapping methods, do not incorporate co-registered T1, T2, and ADC mapping in the heart. Moreover, translating T1, T2, and ADC mapping approaches used in portions of the body, such as the brain, to cardiac imaging of the heart, for example, is not trivial and relatively challenging due to respiratory and cardiac motion that is not present in the brain and some other portions of the body.

One or more example embodiments provide methods, apparatuses (devices), non-transitory computer-readable mediums, computer program products, and other mechanisms, to acquire T1, T2, and diffusion-weighted slice images with Spin-Echo (SE) Echo-Planar Imaging (EPI) readouts encoded under free breathing conditions with varying inversion times (TI), varying echo times (TE), and second-order motion-compensated diffusion gradients (M2) in three orthogonal directions with different b values. The acquired images may be registered to a single target image followed by parameter fitting to generate co-registered T1, T2, and ADC maps. Spin Echo EPI is a rapid MRI technique that combines the principles of spin echo and EPI to achieve relatively fast image acquisition with relatively good contrast. As described herein, T1, T2 and diffusion weighting may be referred to as MRI sequences.

One or more example embodiments allow for free-breathing to improve patient comfort, improve image quality and shorten total scan time (e.g., less repeat scans). Moreover, one or more example embodiments remove the need to co-register images produced by separate scans, decreasing total scan time and the post-processing (computer processing) resources required since the layers of each sequence may be viewed together. One or more example embodiments also facilitate clinical diagnosis and tissue analysis at the voxel level through easier interpretation without the need for contrast agents, thereby enhancing safety and efficiency.

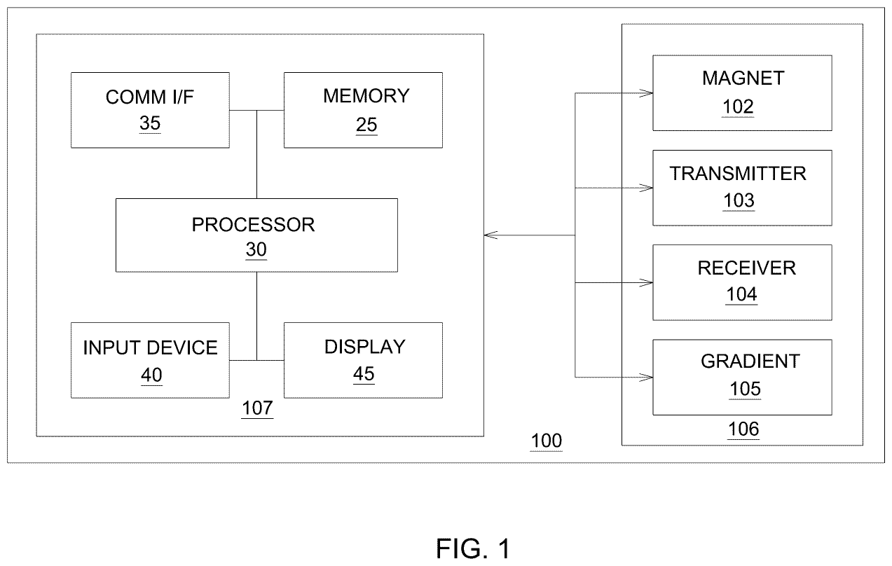

FIG. 1 illustrates a medical imaging system 100 (also referred to more simply as a system) that may be used to implement one or more example embodiments.

Referring to FIG. 1, the system 100 includes hardware 106 and information processing device 107. Hardware 106 may also be referred to as a medical imaging device, an imaging device, or a magnetic resonance imaging (MRI) device.

Hardware 106 includes magnet 102, transmitter 103, receiver 104, and gradient 105. The elements of hardware 106 may be in communication with a processor (not shown), which may also be included in hardware 106. Magnet 102 may include a permanent magnet, a superconducting magnet, or other type of magnet. Transmitter 103 and receiver 104 are part of a radio-frequency (RF) system. Transmitter 103 may include a RF transmitter, a power amplifier, and an antenna (or coil). Receiver 104 may represent a receiver antenna (or coil) and an amplifier. In the example shown in FIG. 1, transmitter 103 and receiver 104 are separately represented. However, in one example, transmitter 103 and receiver 104 may share a common coil. Hardware 106 includes gradient 105. Gradient 105 may represent one or more coils used to apply gradients for localization. Hardware 106 may be configured to acquire images using Spin Echo (SE) Echo Planar Imaging (EPI). Although example embodiments will be described with regard to Spin Echo EPI, example embodiments should not be limited to this example.

Information processing device 107 is operably coupled to, and in communication with, elements of hardware 106. Information processing device 107 includes memory 25, at least one processor (or other processing circuitry) 30, communication interface 35, input device 40 and display 45. Memory 25 may include various special purpose program code including computer executable instructions which may cause processor 30 of information processing device 107 to, in conjunction with hardware 106, cause the system 100 to perform one or more of the methods according to example embodiments described herein. Display 45 may be configured to display one or more quantitative maps generated according to one or more example embodiments. Memory 25 may also store acquired slice images.

In this document, the terms “computer program medium” and “non-transitory computer-readable storage medium” refer to media such as, but not limited to, media at the removable storage drive, a hard disk installed in the hard disk drive, or the first removable storage unit. These computer program products provide software to information processing device 107. Computer programs (also referred to as computer control logic) may be stored in memory 25. Computer programs may also be received via the communications interface. Such computer programs, when executed by a processor, enable the computer system to perform the features and/or operations of the methods discussed herein. For example, memory 25 or other memory may be encoded with computer program code (instructions) for performing operations corresponding to various processes disclosed herein.

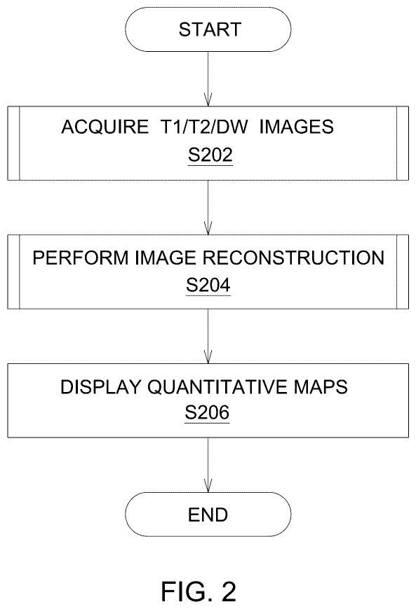

FIG. 2 is a flow chart illustrating a method for co-registered parametric mapping, according to example embodiments. The method shown in FIG. 2 will be discussed with regard to the system 100 shown in FIG. 1 for example purposes. However, example embodiments should not be limited to this example.

Referring to FIG. 2, at S202 the system 100 acquires the multiple series of T1, T2 and diffusion weighted slice images of a region of interest (ROI) (e.g., a region including at least a portion of the heart and myocardial tissue) of a patient. In one example, the information processing device 107 controls the system 100 to acquire the multiple series of slice images. As described in more detail later, the system 100 acquires the T1 weighted slice images with non-selective adiabatic inversion pulses and interleaved slice acquisition; the system 100 acquires the T2 weighted slice images by varying the echo times TE between series of slice images; and the system 100 acquires the diffusion weighted slice images by applying M2 motion compensated diffusion gradients with different b values and/or directions. The T1, T2 and diffusion weighted slice images may be acquired sequentially and in any order under free-breathing conditions, wherein each T1, T2 and diffusion weighted slice image is acquired during the same cardiac phase, such that the collective slice images are acquired over a first image acquisition time period. In one example, T1, T2 and diffusion weighted slice images are acquired using a Spin Echo EPI sequence over 256 heartbeats, such that the image acquisition occurs over a period of about 4-5 minutes. Example embodiments should not, however, be limited to this example.

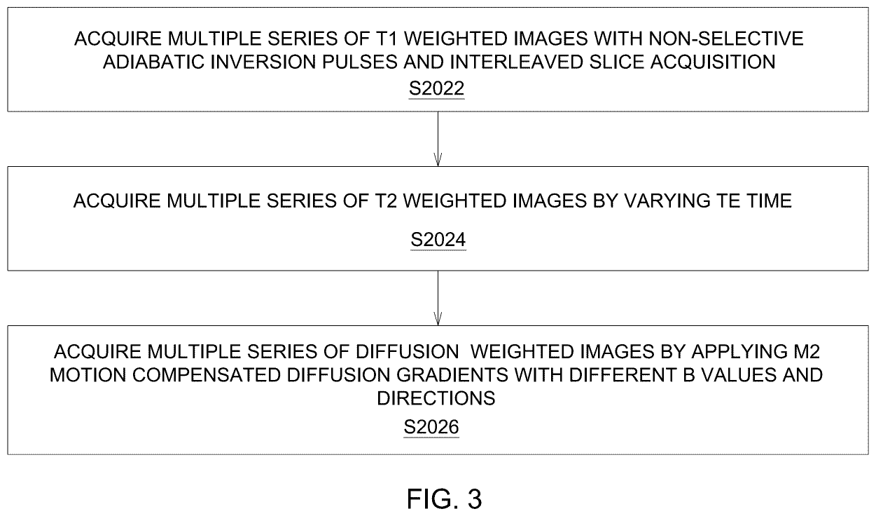

Methods for acquisition of T1, T2 and diffusion weighted slice images, according to example embodiments, will be discussed in more detail below with regard to FIGS. 3-6B.

FIG. 3 is a flow chart illustrating a method for acquiring a plurality of (multiple) series of slice images, according to example embodiments. The method shown in FIG. 3 will be discussed with regard to an example order and with regard to the system 100 shown in FIG. 1. However, example embodiments should not be limited to these examples. Rather, for example, the T1, T2 and diffusion weighted slice images may be obtained in any order. Additionally, example embodiments will be described herein with regard to example numbers of acquisitions and slices or slice images in a series (e.g., 5 for T1, T2 and diffusion encoding). However, example embodiments should not be limited to these examples. Rather, any number of acquisitions and/or slices or slice images may be used.

Referring to FIG. 3, at S2022 the system 100 acquires multiple (a plurality of) series of T1 weighted slice images with nonselective adiabatic inversion pulses and interleaved slice acquisition. In one example, for T1 encoding, the system 100 obtains a series of T1 weighted images at different locations (slices) and different inversion times T1, after application of a single nonselective adiabatic inversion pulse with an initial inversion time T1₁ for the first acquired slice image. Interleaved slice acquisition acquires slice images in an order that reduces and/or minimizes cross-talk while increasing and/or maximizing efficiency. In this regard, rather than acquiring slice images sequentially, interleaved acquisition alternates the order of the slices that are acquired.

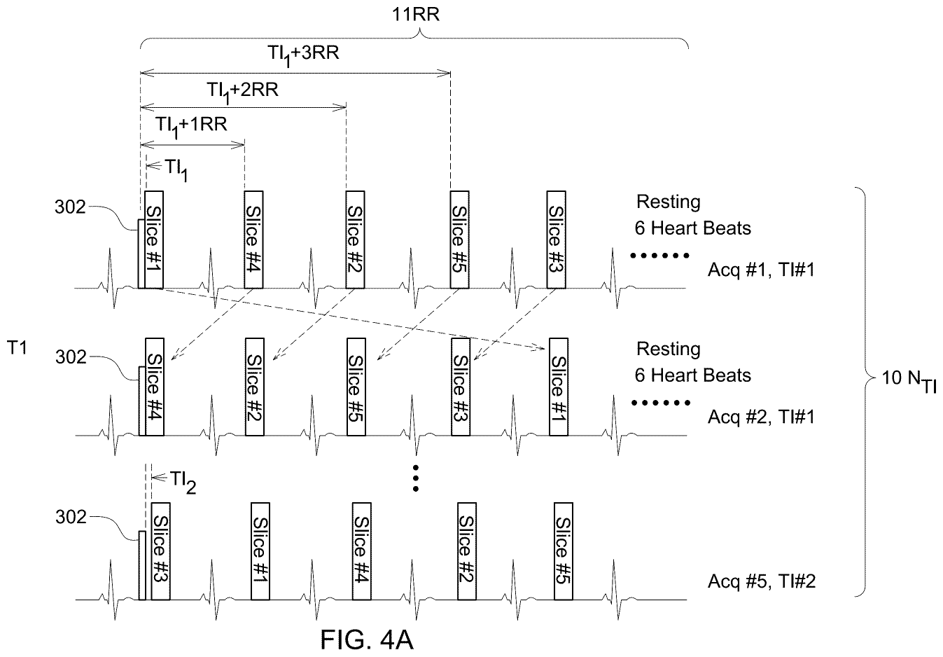

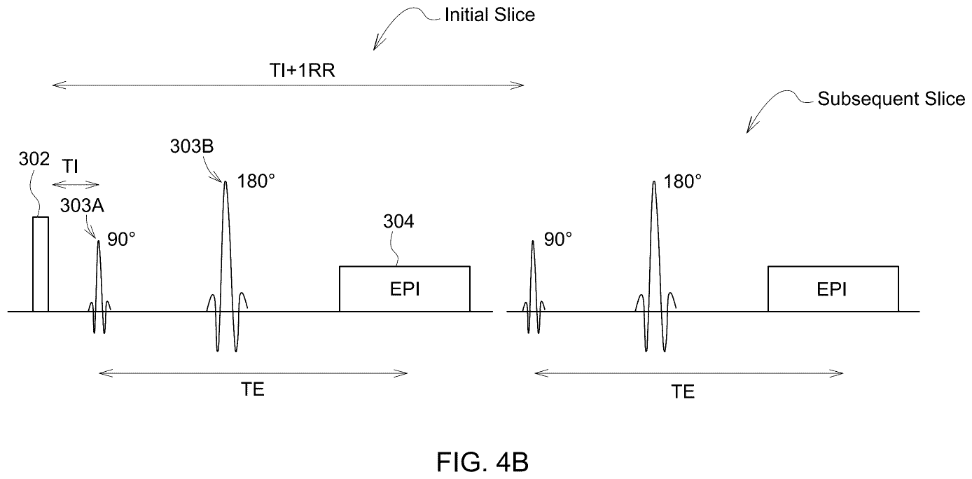

FIG. 4A illustrates a sequence scheme for obtaining multiple series of T1 weighted slice images. In the example shown in FIG. 4A, 10 series of T1 weighted slice images are acquired over 110 heartbeats after application of a single non-selective adiabatic inversion pulse 302 at the start of acquiring each respective series. The non-selective adiabatic inversion pulse 302 is a type of RF pulse in MRI that inverts the magnetization of all tissues within the entire imaging volume uniformly and employs adiabatic inversion by modulating both the amplitude and frequency of the RF field to decrease sensitivity of the inversion to variations in the RF field strength and frequency.

Referring to FIG. 4A, for acquisition of a first series (Acq #1) with inversion time TI₁, after application of the single non-selective adiabatic inversion pulse 302, the system 100 acquires the first series of T1 weighted images at different locations (slices). In more detail, after an initial inversion (delay) time TI₁ after application of the non-selective adiabatic inversion pulse 302, the system 100 acquires T1 weighted slice image Slice #1 at time TI₁, the system 100 acquires T1 weighted slice image Slice #4 at time TI₁+RR, the system 100 acquires T1 weighted slice image Slice #2 at time TI₁+2RR, the system 100 acquires T1 weighted slice image Slice #5 at time TI₁+3RR and the system 100 acquires T1 weighted slice image Slice #3 at time TI₁+4RR. In this example, RR refers to the duration of a heartbeat.

After a resting interval of 6 heartbeats (6RR), another non-selective adiabatic inversion pulse 302 is applied and a second series of T1 weighted images is acquired in a similar manner, except that the order of the slice acquisition is changed and/or shifted. For example, as shown in FIG. 4A, after application of the second non-selective adiabatic inversion pulse 302, the system 100 acquires T1 weighted slice image Slice #4 at time TI₁, the system 100 acquires T1 weighted slice image Slice #2 at time TI₁+1RR, the system 100 acquires T1 weighted slice image Slice #5 at time TI₁+2RR, the system 100 acquires T1 weighted slice image Slice #3 at time TI₁+3RR and the system 100 acquires T1 weighted slice image Slice #1 at time TI₁+4RR. In this example, the system 100 continues the acquisition of series while permuting the slice order to acquire 5 series of T1 weighted images with inversion time TI₁.

The system 100 then obtains 5 series of T1 weighted slice images in the same or substantially manner, except that the inversion time is varied such that the respective slice images in each of the 5 additional series are obtained at TI₂, TI₂+1RR, TI₂+2RR, TI₂+3RR and TI₂+4RR.

For example, as shown in FIG. 4A, in a last acquisition (Acq. #5, TI #2), a non-selective adiabatic inversion pulse 302 is applied and a series of T1 weighted images is acquired in a manner similar to that discussed with regard to the first series, except that the order of the slice acquisition is changed and/or shifted and the inversion time is TI₂, rather than TI₁. In this example, TI₂ is greater than TI₁. For example, after application of the non-selective adiabatic inversion pulse 302, the system 100 acquires T1 weighted slice image Slice #3 at time TI₂, the system 100 acquires T1 weighted slice image Slice #1 at time T2₂+1RR, the system 100 acquires T1 weighted slice image Slice #4 at time TI₂+2RR, the system 100 acquires T1 weighted slice image Slice #2 at time TI₂+3RR and the system 100 acquires T1 weighted slice image Slice #5 at time TI₂+4RR.

In the example shown in FIG. 4A, the system 100 performs 10 acquisitions of T1 weighted slice images such that 10 series of slice images and 10 sampling points with TI₁, TI₂, TI₁+RR, TI₂+RR, TI₁+2RR, TI₂+2RR, . . . , TI₁+4RR, and TI₂+4RR are acquired.

For each series of T1 weighted slice images, acquisition of the slice images are separated by a duration of one heartbeat. However, example embodiments should not be limited to this example.

The system 100 may store the acquired series of T1 weighted slice images in, for example, memory 25.

FIG. 4B illustrates a Spin Echo EPI sequence diagram for acquisition of T1 weighted slice images according to example embodiments. As will be described below, the pulse sequence for acquiring each slice image in a series of slice images is similar, with the exception of the nonselective adiabatic inversion pulse 302, which is only applied prior to acquisition of the first slice image in a respective series.

Referring to FIG. 4B, to acquire a series of T1 weighted slice images, the system 100 applies the single non-selective adiabatic inversion pulse 302 to the imaging volume (e.g., a region of interest including the heart of a patient). The system 100 then applies an initial 90° RF pulse 303A to the imaging volume at inversion time TI to flip the magnetization into the transverse plane. The system 100 then applies a 180° RF pulse 303B at half of the echo time

$$\frac{TE}{2}$$

to refocus the spin (intrinsic angular momentum) and create spin echo. Also during the application of the 90° RF pulse 303A and the 180° RF pulse 303B, the system 100 applies a slice selection gradient to select the particular slice to be imaged.

After the 180° RF pulse 303B is applied, the system 100 generates a series of gradient echoes by switching the readout gradient to form the EPI readout train 304, thereby capturing the T1 weighted slice image, in the form of multiple lines of k-space, in a single shot.

As shown in FIG. 4B, the pulse sequence for obtaining subsequent T1 weighted slice images in a respective series is the same, except that the nonselective adiabatic inversion pulse 302 is not applied.

Returning to FIG. 3, at S2024 the system 100 acquires multiple (a plurality of) series of the T2 weighted slice images by varying echo times TE between the series acquisitions.

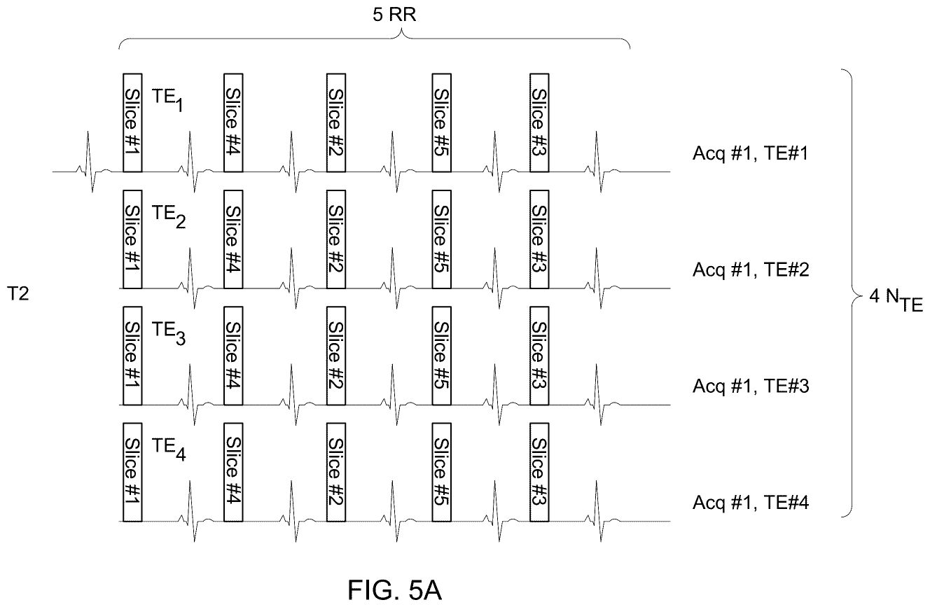

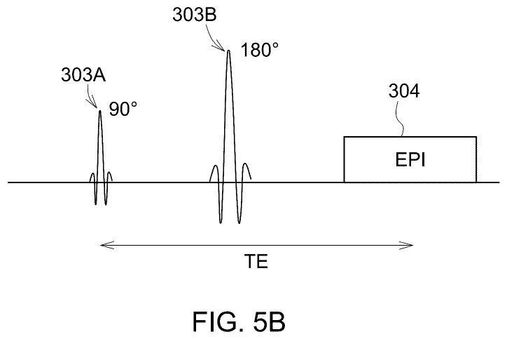

FIG. 5A illustrates a sequence scheme for obtaining multiple (a plurality of) series of T2 weighted slice images, according to example embodiments. In the example shown in FIG. 5A, 4 series of T2 weighted slice images are acquired over 20 heartbeats. However, example embodiments should not be limited to this example.

As shown in FIG. 5A, the system 100 acquires a series of T2 weighted slice images for each of echo times TE₁, TE₂, TE₃, TE₄. In this example, the system 100 acquires the T2 weighted slice images in each series in the order: Slice #1, Slice #4, Slice #2, Slice #5 and Slice #3, wherein the acquisition of adjacent slice images in the series is spaced apart by one heartbeat and the acquisition of the series of T2 weighted slice images occurs over 5 heartbeats (5RR). Example echo times include 35, 40, 50, 60, 70, 80, and 100 ms.

The system 100 may store the acquired series of T2 weighted slice images in, for example, memory 25.

FIG. 5B illustrates a Spin Echo EPI sequence diagram for acquisition of T2 weighted slice images, according to example embodiments.

The process for acquiring a slice image in the series of T2 weighted slice images is similar to the process for obtaining T1 weighted slice images, except that the nonselective adiabatic inversion pulse is not applied and the timing parameters (e.g., echo time TE) differ. In one example, whereas acquisition of a T1 weighted slice image may have an echo time TE of 40 ms, acquisition of a T2 weighted slice image may utilize an echo time TE of 35-140 ms.

In more detail with regard to FIG. 5B, to acquire a T2 weighted slice image, the system 100 applies the initial 90° RF pulse 303A to the imaging volume to flip the magnetization into the transverse plane and then applies the 180° RF pulse 303B at half of the echo time

$$\frac{TE}{2}$$

to refocus the spin and create spin echo. Also during the application of the 90° RF pulse 303A and the 180° RF pulse 303B, the system 100 applies the slice selection gradient to select the particular slice to be imaged.

After application of the 180° RF pulse 303B, the system 100 generates a series of gradient echoes by switching the readout gradient to form the EPI readout train 304, thereby capturing the T2 weighted slice image, in the form of multiple lines of k-space, in a single shot.

Returning again to FIG. 3, at S2026 the system 100 acquires multiple series of diffusion weighted (DW) slice images by applying M2 motion compensated diffusion gradients with different b values and/or directions.

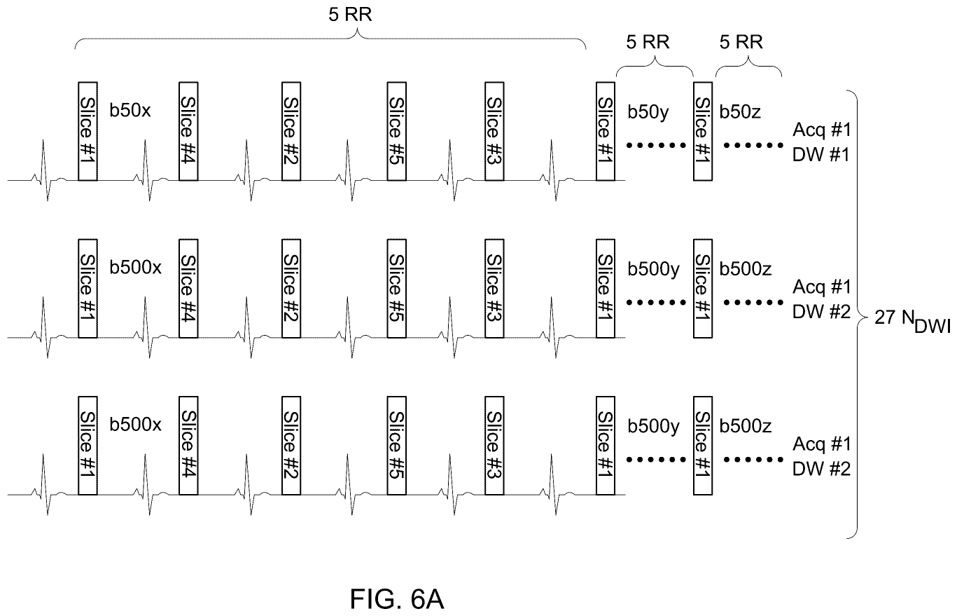

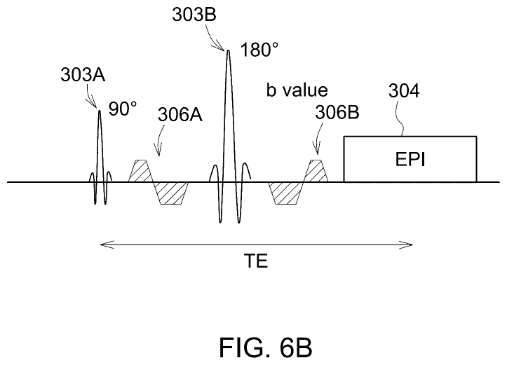

FIG. 6A illustrates a sequence scheme for obtaining multiple (a plurality of) series of diffusion weighted slice images. In the example shown in FIG. 6A, 27 series of diffusion weighted slice images are acquired over 135 heartbeats. However, example embodiments should not be limited to this example.

Referring to FIG. 6A, the system 100 acquires multiple (a plurality of) series of diffusion weighted slice images at the 5 slice locations (Slice #1-Slice #5) at different diffusion gradients and directions. In one example, the diffusion gradients and directions may include b50x (b=50 s/mm²; direction x), b50y (b=50 s/mm²; direction y), b50z (b=50 s/mm²; direction y), b500x (b=500 s/mm²; direction x), b500y (b=500 s/mm²; direction y), b500z (b=500 s/mm²; direction z), etc.).

In the example shown in FIG. 6A, the system 100 acquires a first series of diffusion weighted slice image (Slice #1, Slice #4, Slice #2, Slice #5, Slice #3) at diffusion weighting b50x, a second series of diffusion weighted slice images (Slice #1, Slice #4, Slice #2, Slice #5, Slice #3) at diffusion weighting b50y and a third series of diffusion weighted slice images (Slice #1, Slice #4, Slice #2, Slice #5, Slice #3) at diffusion weighting b50z. The system 100 also acquires similar series of diffusion weighted slice images at diffusion weightings b500x, b500y and b500z. In this example, the system 100 may perform 8 acquisitions of each series of diffusion weighted slice images at each of b values b500x, b500y and b500z to obtain a total of 27 series of diffusion weighted slice images; that is 1 of each of b50x, b50y and b50z and 8 of each of b500x, b500y and b500z. The respective single shot acquisitions in the 5 slice locations are again separated by the duration of the heartbeat. A first series of slice images acquired at b500x, b500y and b500z may be obtained concurrently with the series of slice images at b50x, b50y and b50z, such that the series of diffusion weighted slice images are acquired over an interval of 135 heartbeats.

FIG. 6B illustrates a Spin Echo EPI sequence diagram for acquisition of a diffusion weighted slice image, according to example embodiments.

Referring to FIG. 6B, as with the T1 and T2 weighted slice image acquisition, the system 100 applies the initial 90° RF pulse 303A to the imaging volume to flip the magnetization into the transverse plane and the 180° RF pulse 303B at half of the echo time

$$\frac{TE}{2}$$

to refocus the spin and create spin echo. Additionally, after the initial 90° RF pulse 303A, the system 100 applies diffusion-sensitizing gradients 306A and 306B. In this example, the gradients 306A and 306B around the 180° RF pulse 303B are asymmetric motion compensation gradients. According to one or more example embodiments, the diffusion encoding employs M2 diffusion gradients to provide nulling for zeroth-, first-, and second-order gradient moments with asymmetric bipolar diffusion gradients. The strength and duration of the gradients 306A and 306B determine the b value for acquiring the diffusion weighted slice images.

The system 100 may store the acquired series of diffusion weighted slice images in, for example, memory 25.

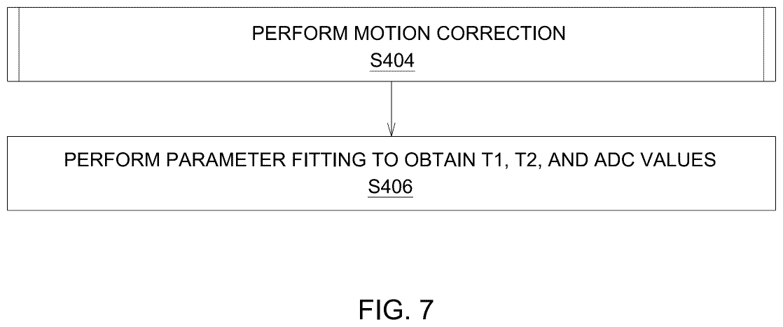

Returning now to FIG. 2, once having acquired the T1, T2 and diffusion weighted slice images, at S204 the information processing device 107 performs image reconstruction on the T1, T2 and diffusion weighted slice images to obtain corresponding T1, T2 and DWI mappings. An example embodiment of the image reconstruction will be discussed in more detail below with regard to FIGS. 7-9B.

FIG. 7 is a flow chart illustrating an example embodiment of a method for image reconstruction at S204 in FIG. 2.

Referring to FIG. 7, at S404 the information processing device 107 performs (e.g., respiratory) motion correction on the acquired slice images to ensure co-registration of the acquired slice images. The slice images may co-registered to a single target image, such as the first T2 weighted slice image as this slice image may have the highest signal-to-noise ratio (SNR).

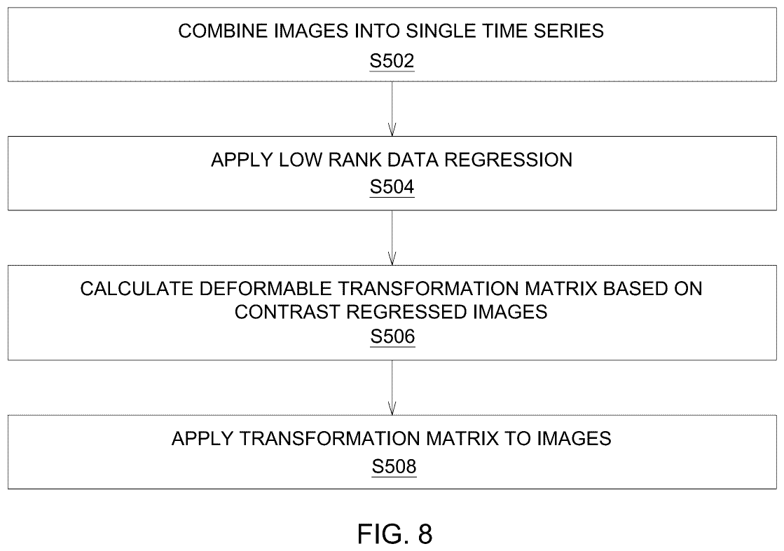

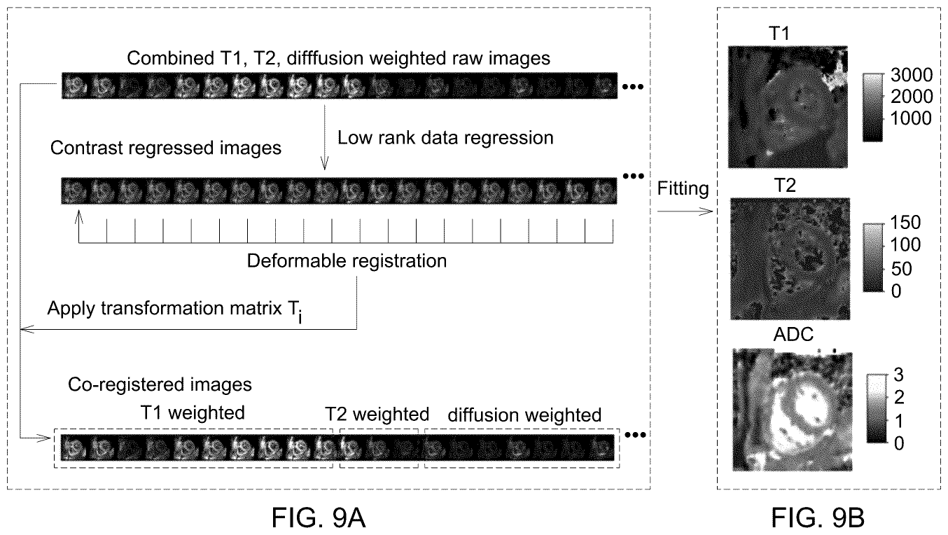

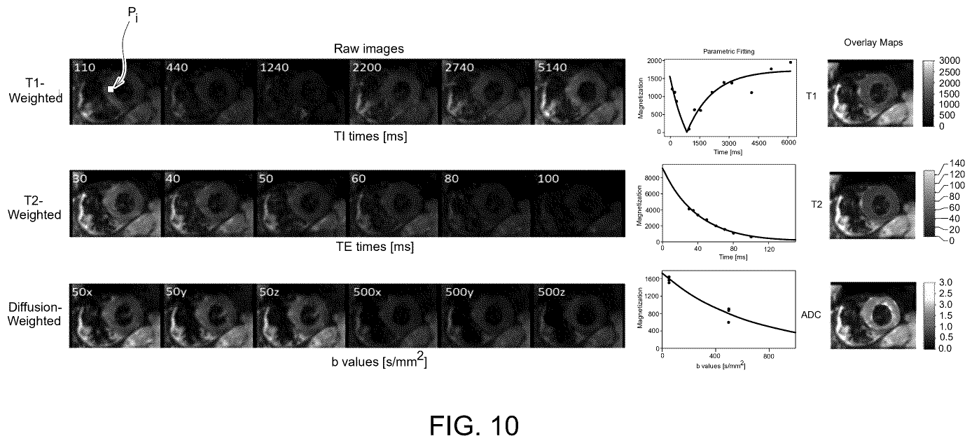

FIG. 8 is a flow chart illustrating an example embodiment of a method for motion correction at S404 in FIG. 8. FIG. 9A is a visual representation of the example embodiment shown in FIG. 8.

Referring to FIGS. 8 and 9A, at S502 the information processing device 107 combines the multiple series of single-shot slice images into a single time series. Because methods for combining series of single-shot slice images into a single time series are generally known, a detailed discussion is omitted.

At S504, the information processing device 107 applies a low rank data regression algorithm to the combined slice images to obtain a set of contrast regressed images. Because algorithms for low rank data regression are generally known, a detailed discussion is omitted.

At S506, the information processing device 107 calculates a deformable transformation matrix based on the contrast regressed images. Because algorithms for calculating deformable transformation matrices is generally known, a detailed discussion is omitted.

At S508, the information processing device 107 applies the calculated deformable transformation matrix to the contrast regressed images to perform motion correction and align the images to a target image, thereby co-registering the T1, T2 and diffusion weighted images. Because methods for motion correction and co-registration such as that discussed with regard to S508 are generally known, a detailed discussion is omitted.

Returning to FIG. 7, at S406, the information processing device 107 performs individual parameter fitting to obtain T1, T2 and ADC values from which to derive T1, T2 and ADC maps for display. According to at least one example embodiment, the T1, T2 and diffusion weighted slice images may be individually fit to derive the T1, T2, and ADC maps, using signal models.

For example, the T1 weighted slice images may be fit using the signal model given by Equation [1] shown below.

$$S ( {TI}_{i} ) = \vert {r}_{a} + {r}_{b} {e}^{- \frac{{TI}_{i}}{{T}_{1}}} \vert \qquad [ 1 ]$$

In this example, S (Tli) is the signal intensity at a pixel in the i^{th} T1 weighted slice image, and rₐ and r_{b} are real value parameters characterizing overall proton density absorption, imperfect inversion pulse) (180°, and other systematic errors. Tli is the inversion time for the i^{th} image and T1 is the T1 (longitudinal) relaxation time obtained by the parameter fit.

The T2-weighted slice images may be fit using the signal model given by Equation [2] shown below.

$$S ( {TE}_{i} ) = {S}_{0} {e}^{- \frac{{TE}_{i}}{{T}_{2}}} \qquad [ 2 ]$$

In this example, S(TEᵢ) is the signal intensity at a pixel in the i^{th} T2 weighted image, S₀ is the initial signal intensity, TEᵢ is the echo time for acquiring the i^{th} T2 weighted slice image, and T2 is the T2 (transverse) relaxation time obtained by the parameter fit.

The diffusion weighted slice images may be fit using the signal model given by Equation [3] shown below.

$$S ( {DWI}_{i} ) = {S}_{0} {e}^{- b \times {D}_{i}} \qquad [ 3 ]$$

In Equation [3], S(DWIᵢ) is the signal intensity at a pixel in the i^{th} diffusion weighted image, S₀ is the initial signal intensity, b is the b value for acquiring the i^{th} diffusion weighted slice image, and Di is the Apparent Diffusion Coefficient (ADC) for the i^{th} diffusion weighted slice image.

The information processing device 107 may calculate ADC values by averaging the D from all diffusion encoding directions (x, y, z) according to Equation [4] shown below.

$$ADC = \frac{{D}_{x} + {D}_{y} + {D}_{z}}{3} \qquad [ 4 ]$$

Referring again back to FIG. 2, at S206, the information processing device 107 displays one or more of the T1, T2 and ADC maps via the display 40. In one example, the imaging processing device 107 may display each of the T1, T2, and ADC maps overlayed with one another. The resulting T1 map is a visual representation where each voxel is color-coded according to its T1 relaxation time. T1 maps show variations in T1 relaxation times, which can indicate different tissue characteristics. The resulting T2 map is a visual representation where each voxel is color-coded according to its T2 relaxation time. T2 maps highlight variations in T2 relaxation times, with areas of high water content appearing brighter. The ADC map is a visual representation of ADC values displayed as a parametric map, which provides a quantitative measure of water diffusion. Higher ADC values may indicate freer water mobility, while lower ADC values suggest restricted diffusion.

According to one or more example embodiments, myocardial tissue composition and/or objective assessment of both focal and diffuse diseases may be performed (e.g., by the information processing device 107) based on the quantitative maps generated at S206 in FIG. 2.

FIG. 9B illustrates an example T1 map, T2 map and ADC map resulting from the parameter fitting.

As described similarly above, after motion correction, slice images with different contrast weightings are grouped into separate T1-weighted, T2-weighted, and diffusion-weighted image groups. These groups are individually fitted using the signal models given by Equations [1]-[4] described above to derive the T1, T2, and ADC maps. FIG. 9B illustrates resulting T1, T2, and ADC maps for this subject at the apical slice.

FIG. 10 illustrates example images with different contrast weightings, representative curve fits from parametric mappings at the pixel Pi in the image with TI=110 ms, and the T1, T2, and ADC maps acquired from this set of images at the basal slice.

Example embodiments were tested on a 3T MRI scanner in phantom measurements, 12 healthy volunteers, a myocardial infarction (MI) swine, and a patient with cardiac amyloidosis (CA) by comparing to reference techniques.

T1 and T2 mapping with co-registered parametric EPI was evaluated in a NiCl₂-doped agarose phantom producing a range of physiological T1 and T2 values (T1=200-2000 ms; T2=20-200 ms) in various states (TIMES). To validate co-registered parametric EPI ADC mapping, a separate phantom was constructed with 7 vials of 0%, 2.5%, 5%, 7.5%, 10%, 17.5%, 25% w/v sucrose in distilled water, and scanned after 30 min equilibrium in ice water to avoid fluctuations in temperature. co-registered parametric EPI images were acquired using a prototype spin-echo sequence with single-shot EPI readout. The co-registered parametric EPI T1 mapping sequence used a slice selective inversion pulse and varying TI times (110, 210, 310, 910, 1240, 1540, 2140, 2740, 3140, 4140, 5140, and 6140 ms) with fixed TE (40 ms) and b=0 s/mm². The co-registered parametric EPI T2 mapping sequence employed varying TEs (35, 40, 50, 60, 70, 80, and 100 ms) with no inversion and b=0 s/mm². The co-registered parametric EPI ADC mapping sequence used optimized M2 diffusion gradients with b=50 s/mm² (reference, one average), b=500 s/mm² (four averages), and diffusion encoding along three orthogonal directions, no inversion, and fixed TE (65 ms). Reference T1/T2 maps were obtained using an inversion-recovery spin-echo (IR-SE) sequence, and a T2-weighted spin-echo (T2-SE) sequence, respectively, with the same TI times, and TE times as in co-registered parametric EPI. A reference ADC map was acquired using a state-of-the-art motion-compensated optimized diffusion encoding (MODE) single-shot EPI (SS-EPI) sequence that has been validated before, with the same diffusion encodings and the same number of averages as in co-registered parametric EPI.

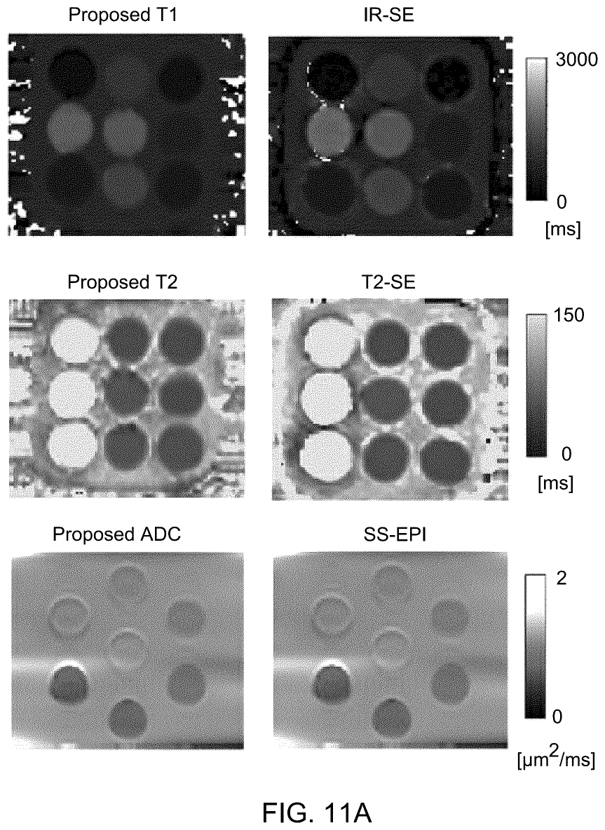

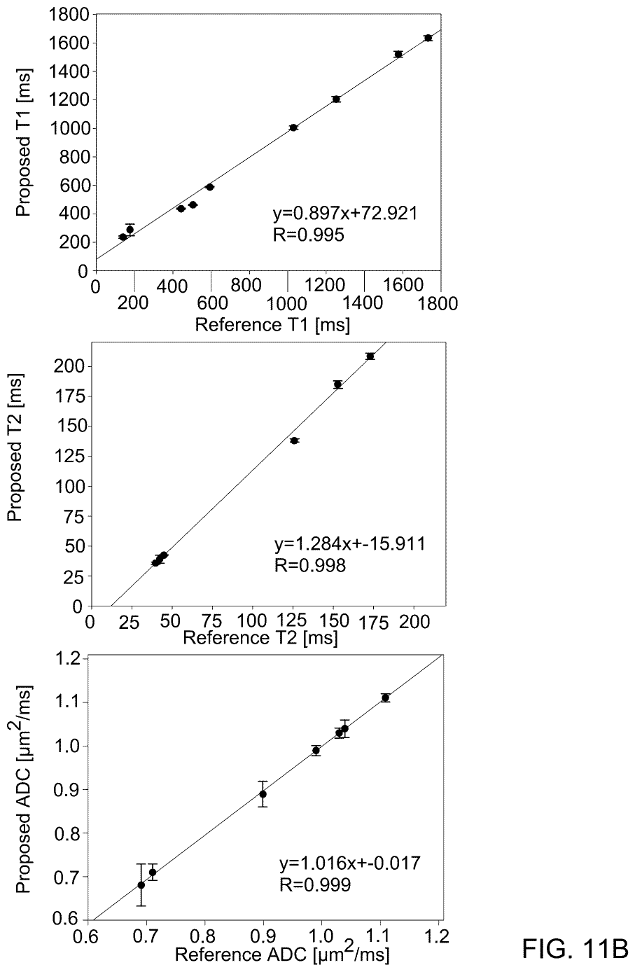

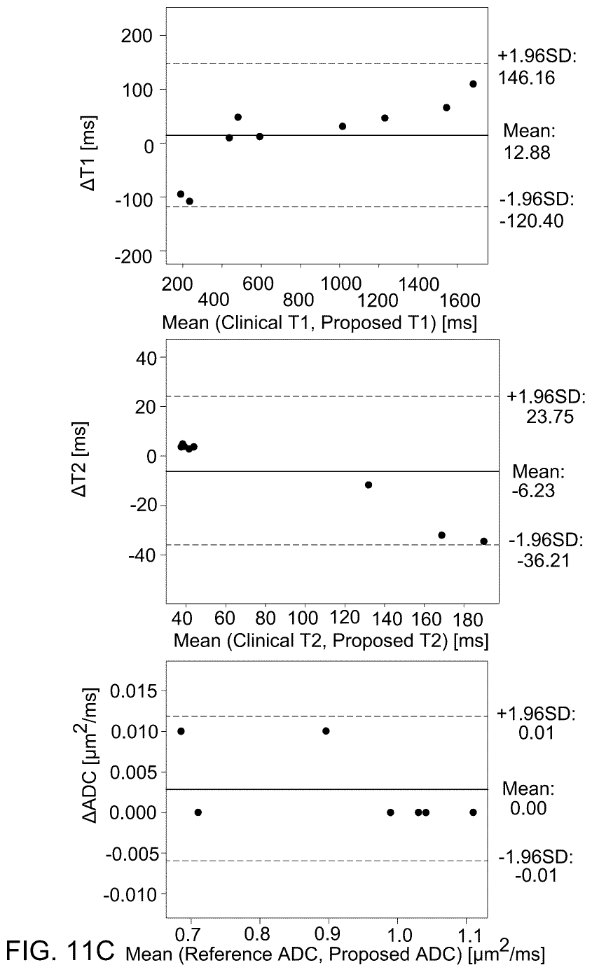

FIGS. 11A-11C illustrate example T1, T2, and ADC quantification results in phantoms. More specifically, FIG. 11A illustrates T1, T2, and ADC maps acquired from co-registered parametric EPI and inversion recovery spin echo, T2 weighted spin echo, and single-shot spin echo EPI readout for TIMES phantom and a diffusion phantom. FIG. 11B illustrates the correlation plot between co-registered parametric EPI measurements and reference measurements, with correlation coefficients labeled (R>0.99). In this example, quantification was done inside circular regions of interest (ROIs) for every sample tube. FIG. 11C are Bland-Altman plots comparing co-registered parametric EPI's T1, T2, and ADC measurements with their respective references.

In above-discussed example, a substantial correlation (R=0.995/0.998/0.999 for T1/T2/ADC respectively) was found between co-registered parametric EPI and reference measurements. The fitted slopes through regression analysis were 0.897/1.284/1.016 for T1/T2/ADC, respectively.

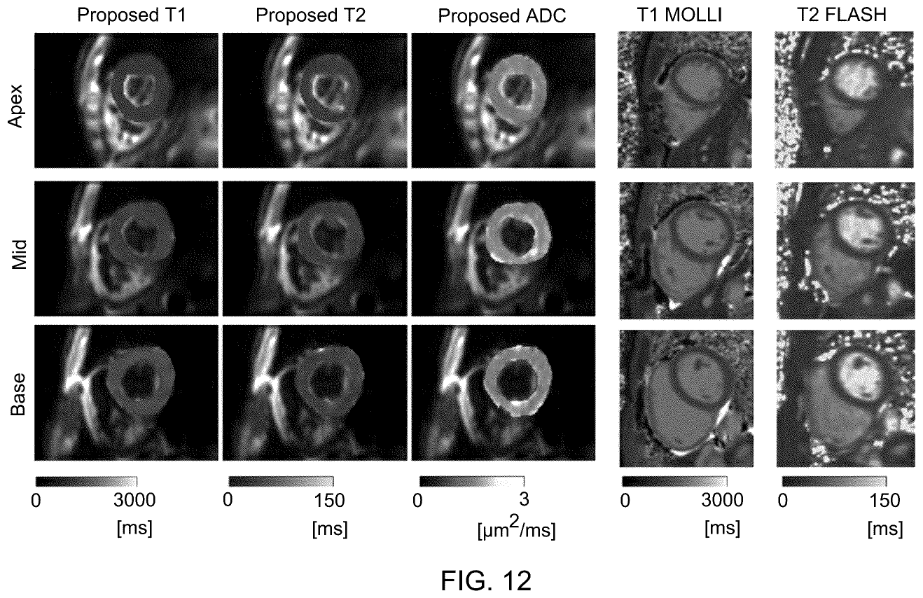

In another test, twelve healthy volunteers (10 females, 26.5±16 years old), with no known history of cardiovascular disease were recruited under a research protocol approved by the Institutional Review Board of the Cleveland Clinic (Cleveland, OH). All co-registered parametric EPI and reference images were acquired in short-axis views (basal, midventricular, and apical slices) identified using a bSSFP cine acquisition with an in-plane resolution of 1.3×1.3 mm². For co-registered parametric EPI, each measurement was ECG triggered to achieve imaging in end systole and employed a 2D single-shot EPI readout. Clinical reference maps were acquired in the same imaging views using commercially available T1-MOLLI and T2-FLASH mapping with an end-expiration breath-hold and triggering to the end-diastolic cardiac phase. FIG. 12 illustrates representative maps in such a healthy volunteer. Specifically, FIG. 12 illustrates T1, T2, ADC quantitative maps in a representative healthy subject at the basal, middle, and apical slices comparing with clinical sequences MOLLI and FLASH.

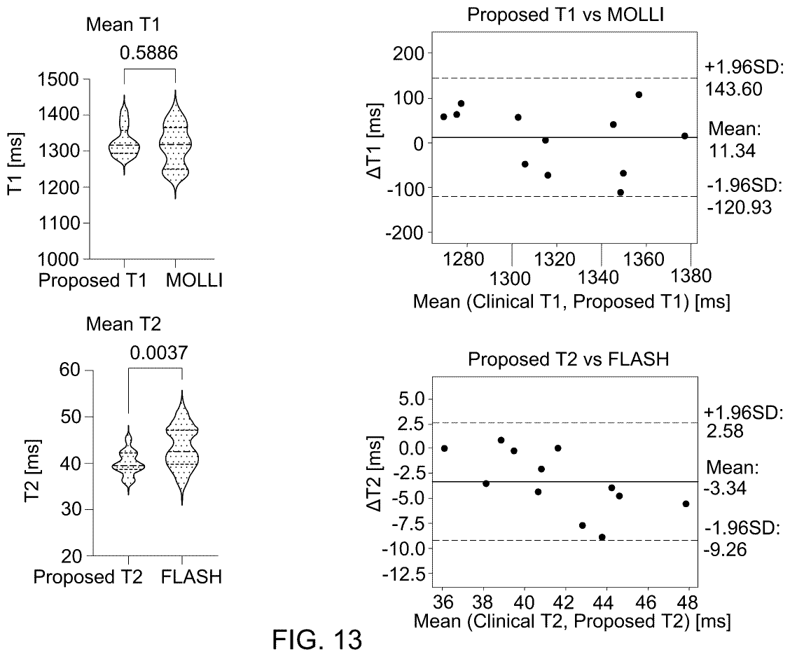

FIG. 13 illustrates averaged T1 and T2 values over all 12 healthy volunteers. More specifically, FIG. 13 shows violin plots of the mean of T1 (top) and T2 (bottom) values recorded globally across all 12 subjects and Bland-Altman plots (right) comparing the global values recorded across all subjects.

Statistical analysis indicated no significant difference in parameter estimations between co-registered parametric EPI T1 and T1-MOLLI for all short-axis slices (mean T1±1 standard deviation across 12 healthy subjects: 1350±51 ms vs. 1316±54 ms, p=0.3143), while the mean of co-registered parametric EPI T2 was significantly lower than T2-FLASH (mean T2±1 standard deviation across 12 healthy subjects: 39.9±1.9 ms vs. 43.4±3.7 ms, p=0.0037). Bland-Altman analyses of T1 and T2 mapping methods in the global myocardium are shown with the following limit of agreements: T1: +211 ms; T2: +6.2 ms. ADC was compared with conventional values and was within the normal range (1.55±0.09 μm²/ms).

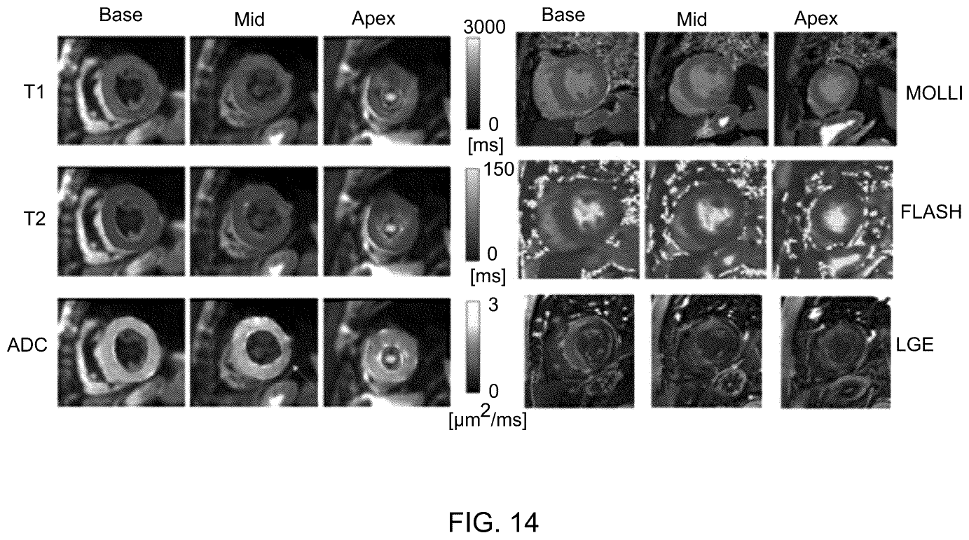

FIG. 14 illustrates multiparametric maps and clinical sequences on a 74-year-old male with clinically suspected cardiac amyloidosis. In this case, LGE revealed global LV subendocardial enhancement and a dark blood pool. Through visual comparison, the areas of Late gadolinium enhancement (LGE) hyperenhancement corresponded well with the regions of high values in the ADC maps in the mid-cavity inferior segments, while T1 and T2 maps were not sensitive to such hyperenhancement. Elevated global T1, T2, and ADC values (Mean±1 SD) were observed in both co-registered parametric EPI (1445±162 ms, 45.6±9.4 ms, 1.73±0.24 μm²/ms for T1/T2/ADC, respectively) and clinical sequences (1415±59 ms and 45.3±9.4 ms for T1/T2, respectively).

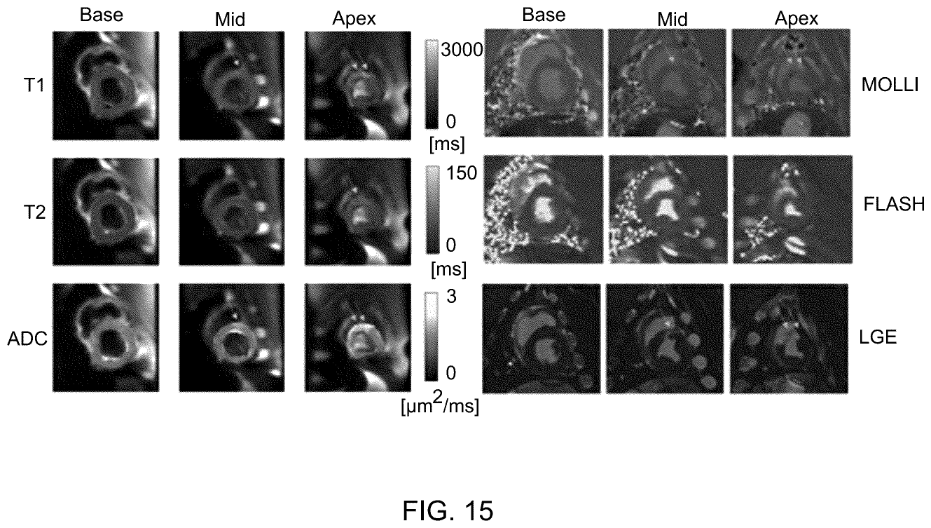

FIG. 15 illustrates example multiparametric maps and clinical sequences on a myocardium infarction (MI) swine one week after left anterior descending artery occlusion. LGE images are shown in the bottom right for scar visualization. In the MI swine scanned one week after a 90-minute occlusion of the left anterior descending artery under an Institutional Animal Care and Use Committee (IACUC) approved protocol, LGE revealed a large region of enhancement in the mid-cavity anterior segment and anterior and septal segments at the apical short-axis slice. Elevated T1 (1413±202 ms, mean±1 SD, same below), T2 (43.8±7.7 ms), and ADC (1.79±0.2 μm²/ms) were observed in the enhancement area compared with the remote myocardium (1314.8±112 ms/40.0±6.9 ms/1.55±0.1 μm²/ms for T1/T2/ADC, respectively) in co-registered parametric EPI. Similar results were observed in clinical T1 and T2 maps with T1=1332±72 ms, T2=47.2±10.0 ms for the infarct region, and T1=1284±61 ms, T2=43.66±6.9 ms for the remote region.

Furthermore, to quantify the effectiveness of in-plane motion correction, LV epicardial and endocardial borders were manually segmented across all slices before and after motion correction. The comparison of the total LV area of misregistration was performed between the raw images and motion-corrected co-registered parametric EPI T1-weighted, T2-weighted, and diffusion-weighted images, with reference to the target image, using a three-way analysis of variance test.

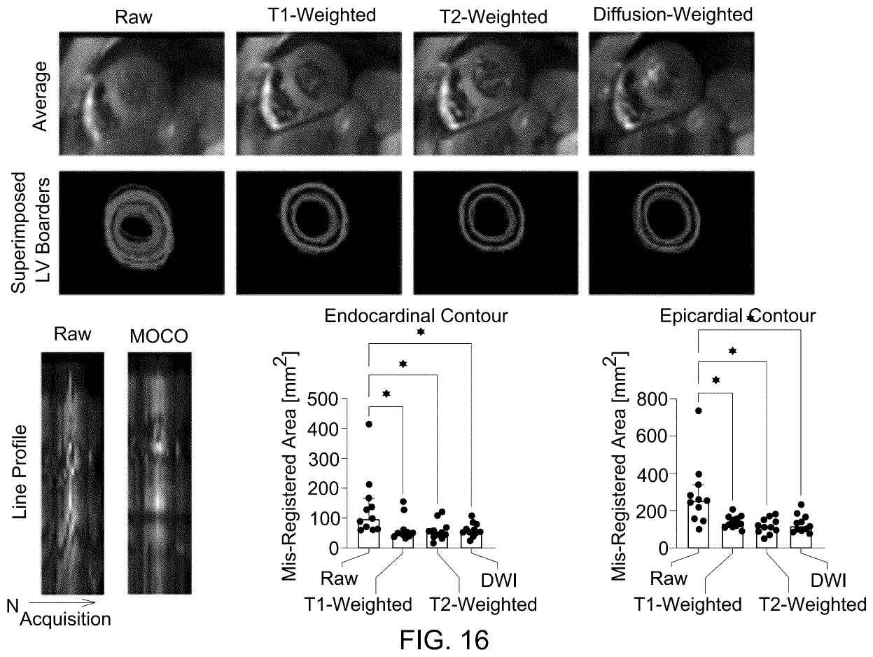

FIG. 16 illustrates example effectiveness of motion correction in connection with example embodiments.

As shown in FIG. 16, following motion correction, significant decreases in endocardium mis-registration area were found when compared to naïve free-breathing raw images. Significant decreases in epicardium mis-registration area were also observed when compared to raw images before motion correction (p=0.044, p=0.023, p=0.249, for T1, T2, and diffusion weighted images, respectively). The endocardium mis-registration areas were 137±104, 64±39, 58±31, 61±22 mm², for raw images, T1-weighted, T2-weighted, and diffusion-weighted, respectively. Similar results were found for epicardium misregistration area: 285±172, 140±33, 117±41, 131±48 mm² for raw images, T1-weighted, T2-weighted, and diffusion-weighted, respectively.

One or more example embodiments provide co-registered, free-breathing myocardial T1, T2, and ADC multiparametric maps of 3-slice in a 12.5-min scan, which may promote patient comfort and/or improve clinical analysis with multiple co-registered quantitative tissue characterizations.

The following is a list of non-limiting illustrative embodiments disclosed herein:

Illustrative embodiment 1. A medical imaging system comprising: a memory storing computer-executable instructions; and at least one processor configured to execute the computer-executable instructions to cause the medical imaging system to acquire a plurality of series of slice images of at least a portion of a heart of a patient using spin-echo echo planar imaging readouts and a plurality of different magnetic resonance imaging sequences, and to generate a plurality of co-registered parametric mappings based on the plurality of series of slice images, each of the plurality of co-registered parametric mappings corresponding to a magnetic resonance imaging sequence among the plurality of different magnetic resonance imaging sequences.

Illustrative embodiment 2. The medical imaging system of illustrative embodiment 1, wherein the plurality of co-registered parametric mappings provide quantitative characterization of the portion of the heart.

Illustrative embodiment 3. The medical imaging system of illustrative embodiment 1 or 2, wherein the at least one processor is configured to execute the computer-executable instructions to cause the medical imaging system to display the plurality of co-registered parametric mappings.

Illustrative embodiment 4. The medical imaging system of illustrative embodiment 3, wherein the at least one processor is configured to execute the computer-executable instructions to cause the medical imaging system to display the plurality of co-registered parametric mappings overlayed on one or more of the slice images.

Illustrative embodiment 5. The medical imaging system of any of the preceding illustrative embodiments, wherein the plurality of different magnetic resonance imaging sequences include T1, T2 and diffusion encoding.

Illustrative embodiment 6. The medical imaging system of any of the preceding illustrative embodiments, wherein the plurality of series of slice images are acquired under free breathing conditions.

Illustrative embodiment 7. The medical imaging system of any of the preceding illustrative embodiments, wherein the plurality of series of slice images include a plurality of series of T1 weighted slice images, a plurality of series of T2 weighted slice images and a plurality of series of diffusion weighted slice images.

Illustrative embodiment 8. The medical imaging system of illustrative embodiment 7, wherein the at least one processor is configured to execute the computer-executable instructions to cause the medical imaging system to acquire the plurality of series of T1 weighted slice images, the plurality of series of T2 weighted slice images and the plurality of series of diffusion weighted slice images during the same cardiac phase.

Illustrative embodiment 9. The medical imaging system of illustrative embodiment 7 or 8, wherein the at least one processor is configured to execute the computer-executable instructions to cause the medical imaging system to acquire the plurality of series of T1 weighted slice images using at least two different inversion times.

Illustrative embodiment 10. The medical imaging system of any of illustrative embodiments 7-9, wherein the at least one processor is configured to execute the computer-executable instructions to cause the medical imaging system to apply a nonselective adiabatic inversion pulse, and acquire at least a first of the plurality of series of T1 weighted slice images with interleaved slice acquisition, wherein acquisition of respective T1 weighted slice images in the first of the plurality of series of T1 weighted slice images is separated by a duration of a heartbeat.

Illustrative embodiment 11. The medical imaging system of illustrative embodiment 10, wherein the at least one processor is configured to execute the computer-executable instructions to cause the medical imaging system to acquire the plurality of series of T2 weighted slice images by varying an echo time used to acquire each of the plurality of series of T2 weighted slice images.

Illustrative embodiment 12. The medical imaging system of illustrative embodiment 11, wherein the at least one processor is configured to execute the computer-executable instructions to cause the medical imaging system to acquire the plurality of series of diffusion weighted slice images by applying second-order motion compensated diffusion gradients with different b values and directions.

Illustrative embodiment 13. The medical imaging system of any of the preceding illustrative embodiments, further comprising: a magnetic resonance imaging device configured to acquire the plurality of series of slice images.

Illustrative embodiment 14. A non-transitory computer-readable storage medium storing computer-executable instructions that, when executed by at least one processor at an medical imaging system, cause the medical imaging system to perform a method for generating a plurality of co-registered parametric mappings of at least a portion of a heart of a patient, the method comprising: acquiring a plurality of series of slice images of at least the portion of the heart using spin-echo echo planar imaging readouts and a plurality of different magnetic resonance imaging sequences; and generating the plurality of co-registered parametric mappings based on the plurality of series of slice images, each of the plurality of co-registered parametric mappings corresponding to a magnetic resonance imaging sequence among the plurality of different magnetic resonance imaging sequences.

Illustrative embodiment 15. The non-transitory computer-readable storage medium of illustrative embodiment 14, wherein the plurality of co-registered parametric mappings provide quantitative characterization of the portion of the heart.

Illustrative embodiment 16. The non-transitory computer-readable storage medium of illustrative embodiment 14 or 15, wherein the method further comprises: displaying the plurality of co-registered parametric mappings overlayed on one or more of the slice images.

Illustrative embodiment 17. The non-transitory computer-readable storage medium of any of illustrative embodiments 14-16, wherein the plurality of series of slice images include a plurality of series of T1 weighted slice images, a plurality of series of T2 weighted slice images and a plurality of series of diffusion weighted slice images.

Illustrative embodiment 18. The non-transitory computer-readable storage medium of illustrative embodiment 17, wherein the acquiring acquires the plurality of series of T1 weighted slice images, the plurality of series of T2 weighted slice images and the plurality of series of diffusion weighted slice images during the same cardiac phase.

Illustrative embodiment 19. The non-transitory computer-readable storage medium of illustrative embodiment 17, wherein the acquiring comprises: acquiring at least a first of the plurality of series of T1 weighted slice images with interleaved slice acquisition after applying a nonselective adiabatic inversion pulse, wherein acquisition of respective T1 weighted slice images in the first of the plurality of series of T1 weighted slice images is separated by a duration of a heartbeat, acquiring the plurality of series of T2 weighted slice images by varying an echo time used to acquire each of the plurality of series of T2 weighted slice images, and acquiring the plurality of series of diffusion weighted slice images by applying second-order motion compensated diffusion gradients with different b values and directions.

Illustrative embodiment 20. A method for generating a plurality of co-registered parametric mappings of at least a portion of a heart of a patient, the method comprising: acquiring a plurality of series of slice images of at least the portion of the heart using spin-echo echo planar imaging readouts and a plurality of different magnetic resonance imaging sequences; and generating the plurality of co-registered parametric mappings based on the plurality of series of slice images, each of the plurality of co-registered parametric mappings corresponding to a magnetic resonance imaging sequence among the plurality of different magnetic resonance imaging sequences.

Although the present invention has been described in detail with reference to example embodiments, the present invention is not limited by the disclosed examples from which the skilled person is able to derive other variations without departing from the scope of the invention.

None of the elements recited in the claims are intended to be a means-plus-function element within the meaning of 35 U.S.C. § 112 (f) unless an element is expressly recited using the phrase “means for” or, in the case of a method claim, using the phrases “operation for” or “step for.”

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Specific structural and functional details disclosed herein are merely representative for purposes of describing example embodiments. This invention may, however, be embodied in many alternate forms and should not be construed as limited to only the embodiments set forth herein.

Units and/or devices according to one or more example embodiments may be implemented using hardware, software, and/or a combination thereof. For example, hardware devices may be implemented using processing circuitry such as, but not limited to, a processor, at least one central processing unit (CPU), a controller, an arithmetic logic unit (ALU), a digital signal processor, a microcomputer, a field programmable gate array (FPGA), a System-on-Chip (SoC), a programmable logic unit, a microprocessor, or any other device capable of responding to and executing instructions in a defined manner. Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

For example, when a hardware device is a computer processing device (e.g., a processor, Central At least one processor (CPU), a controller, an arithmetic logic unit (ALU), a digital signal processor, a microcomputer, a microprocessor, etc.), the computer processing device may be configured to carry out program code by performing arithmetical, logical, and input/output operations, according to the program code. Once the program code is loaded into a computer processing device, the computer processing device may be programmed to perform the program code, thereby transforming the computer processing device into a special-purpose computer processing device. In a more specific example, when the program code is loaded into a processor, the processor becomes programmed to perform the program code and operations corresponding thereto, thereby transforming the processor into a special-purpose processor. According to one or more example embodiments, at least one memory may include or store computer program code, and the at least one memory and the computer program code may be configured to, with at least one processor, cause an information processing device and/or an acquisition device to perform the necessary tasks. Additionally, the processor, memory and example algorithms, encoded as computer program code, serve as means for providing or causing performance of operations discussed herein.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

Software may include a computer program, program code, instructions, or some combination thereof, for independently or collectively instructing or configuring a hardware device to operate as desired. The computer program and/or program code may include program or computer-readable instructions, software components, software modules, data files, data structures, and/or the like, capable of being implemented by one or more hardware devices, such as one or more of the hardware devices mentioned above. Examples of program code include both machine code produced by a compiler and higher-level program code that is executed using an interpreter.

Software and/or data may be embodied permanently or temporarily in any type of machine, component, physical or virtual equipment, or computer storage medium or device, capable of providing instructions or data to, or being interpreted by, a hardware device. The software also may be distributed over network coupled computer systems so that the software is stored and executed in a distributed fashion. In particular, for example, software and data may be stored by one or more computer-readable recording mediums, including the tangible or non-transitory computer-readable storage media discussed herein.

Even further, any of the disclosed methods may be embodied in the form of a program or software. The program or software may be stored on a non-transitory computer-readable medium and is adapted to perform any one of the aforementioned methods when run on a computer device (a device including a processor). Thus, the non-transitory, tangible computer-readable medium, is adapted to store information and is adapted to interact with a data processing facility or computer device to execute the program of any of the above mentioned embodiments and/or to perform the method of any of the above-mentioned embodiments.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A medical imaging system comprising:
a memory storing computer-executable instructions; and
at least one processor configured to execute the computer-executable instructions to cause the medical imaging system to
acquire a plurality of series of slice images of at least a portion of a heart of a patient using spin-echo echo planar imaging readouts and a plurality of different magnetic resonance imaging sequences, and
generate a plurality of co-registered parametric mappings based on the plurality of series of slice images, each of the plurality of co-registered parametric mappings corresponding to a magnetic resonance imaging sequence among the plurality of different magnetic resonance imaging sequences.

2. The medical imaging system of claim 1, wherein the plurality of co-registered parametric mappings provide quantitative characterization of the portion of the heart.

3. The medical imaging system of claim 1, wherein the at least one processor is configured to execute the computer-executable instructions to cause the medical imaging system to display the plurality of co-registered parametric mappings.

4. The medical imaging system of claim 3, wherein the at least one processor is configured to execute the computer-executable instructions to cause the medical imaging system to display the plurality of co-registered parametric mappings overlayed on one or more of the slice images.

5. The medical imaging system of claim 1, wherein the plurality of different magnetic resonance imaging sequences include T1, T2 and diffusion encoding.

6. The medical imaging system of claim 1, wherein the plurality of series of slice images are acquired under free breathing conditions.

7. The medical imaging system of claim 1, wherein the plurality of series of slice images include a plurality of series of T1 weighted slice images, a plurality of series of T2 weighted slice images and a plurality of series of diffusion weighted slice images.

8. The medical imaging system of claim 7, wherein the at least one processor is configured to execute the computer-executable instructions to cause the medical imaging system to acquire the plurality of series of T1 weighted slice images, the plurality of series of T2 weighted slice images and the plurality of series of diffusion weighted slice images during the same cardiac phase.

9. The medical imaging system of claim 7, wherein the at least one processor is configured to execute the computer-executable instructions to cause the medical imaging system to acquire the plurality of series of T1 weighted slice images using at least two different inversion times.

10. The medical imaging system of claim 7, wherein the at least one processor is configured to execute the computer-executable instructions to cause the medical imaging system to
apply a nonselective adiabatic inversion pulse, and
acquire at least a first of the plurality of series of T1 weighted slice images with interleaved slice acquisition, wherein
acquisition of respective T1 weighted slice images in the first of the plurality of series of T1 weighted slice images is separated by a duration of a heartbeat.

11. The medical imaging system of claim 10, wherein the at least one processor is configured to execute the computer-executable instructions to cause the medical imaging system to
acquire the plurality of series of T2 weighted slice images by varying an echo time used to acquire each of the plurality of series of T2 weighted slice images.

12. The medical imaging system of claim 11, wherein the at least one processor is configured to execute the computer-executable instructions to cause the medical imaging system to
acquire the plurality of series of diffusion weighted slice images by applying second-order motion compensated diffusion gradients with different b values and directions.

13. The medical imaging system of claim 1, further comprising:
a magnetic resonance imaging device configured to acquire the plurality of series of slice images.

14. A non-transitory computer-readable storage medium storing computer-executable instructions that, when executed by at least one processor at an medical imaging system, cause the medical imaging system to perform a method for generating a plurality of co-registered parametric mappings of at least a portion of a heart of a patient, the method comprising:
acquiring a plurality of series of slice images of at least the portion of the heart using spin-echo echo planar imaging readouts and a plurality of different magnetic resonance imaging sequences; and
generating the plurality of co-registered parametric mappings based on the plurality of series of slice images, each of the plurality of co-registered parametric mappings corresponding to a magnetic resonance imaging sequence among the plurality of different magnetic resonance imaging sequences.

15. The non-transitory computer-readable storage medium of claim 14, wherein the plurality of co-registered parametric mappings provide quantitative characterization of the portion of the heart.

16. The non-transitory computer-readable storage medium of claim 14, wherein the method further comprises:
displaying the plurality of co-registered parametric mappings overlayed on one or more of the slice images.

17. The non-transitory computer-readable storage medium of claim 14, wherein the plurality of series of slice images include a plurality of series of T1 weighted slice images, a plurality of series of T2 weighted slice images and a plurality of series of diffusion weighted slice images.

18. The non-transitory computer-readable storage medium of claim 17, wherein the acquiring acquires the plurality of series of T1 weighted slice images, the plurality of series of T2 weighted slice images and the plurality of series of diffusion weighted slice images during the same cardiac phase.

19. The non-transitory computer-readable storage medium of claim 17, wherein the acquiring comprises:
acquiring at least a first of the plurality of series of T1 weighted slice images with interleaved slice acquisition after applying a nonselective adiabatic inversion pulse, wherein acquisition of respective T1 weighted slice images in the first of the plurality of series of T1 weighted slice images is separated by a duration of a heartbeat,
acquiring the plurality of series of T2 weighted slice images by varying an echo time used to acquire each of the plurality of series of T2 weighted slice images, and
acquiring the plurality of series of diffusion weighted slice images by applying second-order motion compensated diffusion gradients with different b values and directions.

20. A method for generating a plurality of co-registered parametric mappings of at least a portion of a heart of a patient, the method comprising:
acquiring a plurality of series of slice images of at least the portion of the heart using spin-echo echo planar imaging readouts and a plurality of different magnetic resonance imaging sequences; and
generating the plurality of co-registered parametric mappings based on the plurality of series of slice images, each of the plurality of co-registered parametric mappings corresponding to a magnetic resonance imaging sequence among the plurality of different magnetic resonance imaging sequences.
